(19) United States
(12) Patent Application Publication
(10) Pub. No.: US 2025/0149325 A1
(43) Pub. Date: May 8, 2025

(54) METHOD OF CLEANING A SURFACE

(71) Applicant: ASM IP Holding B.V., Almere (NL)

(72) Inventors: Shaoren Deng, Ghent (BE); Andrea Illiberi, Leuven (BE); Daniele Chiappe, Espoo (FI); Eva Tois, Espoo (FI); Giuseppe Alessio Verni, Jodoigne (BE); Michael Givens, Oud-Heverlee (BE); Varun Sharma, Helsinki (FI); Chiyu Zhu, Helsinki (FI); Shinya Iwashita, Helsinki (FI); Charles Dezelah, Helsinki (FI); Viraj Madhiwala, Helsinki (FI); Jan Willem Maes, Wilrijk (BE); Marko Tuominen, Helsinki (FI); Anirudhan Chandrasekaran, Herent (BE)

(21) Appl. No.: 19/014,870

(22) Filed: Jan. 9, 2025

Related U.S. Application Data
(63) Continuation of application No. 17/407,839, filed on Aug. 20, 2021, now Pat. No. 12,217,954.
(60) Provisional application No. 63/069,911, filed on Aug. 25, 2020.
(60) Provisional application No. 63/087,988, filed on Oct. 6, 2020.
(60) Provisional application No. 63/117,018, filed on Nov. 23, 2020.

(51) Int. Cl. H01L 21/02; B08B 3/08; B08B 5/00; C11D 7/02; C11D 7/24; C11D 7/26; C23C 16/02; H01L 21/285

(52) U.S. Cl. CPC H01L 21/02074; B08B 3/08; B08B 5/00; C11D 7/02; C11D 7/245; C11D 7/261; C11D 7/264; C11D 7/265; C23C 16/0227; H01L 21/28562; C11D 2111/22

(57) ABSTRACT

Methods for cleaning a substrate are disclosed. The substrate comprises a dielectric surface and a metal surface. The methods comprise providing a cleaning agent to the reaction chamber.

### CROSS-REFERENCE TO RELATED APPLICATIONS

This application is a continuation of, and claims priority to, U.S. patent application Ser. No. 17/407,839 filed Aug. 20, 2021 and titled METHOD OF CLEANING A SURFACE, which claims priority to U.S. Provisional Patent Application Ser. No. 63/069,911 filed Aug. 25, 2020 titled METHOD OF CLEANING A SURFACE, U.S. Provisional Patent Application Ser. No. 63/087,988 filed Oct. 6, 2020 titled METHOD OF CLEANING A SURFACE, and 63/117,018 filed Nov. 23, 2020 titled METHOD OF CLEANING A SURFACE, the disclosures of which are hereby incorporated by reference in their entirety.

### FIELD OF INVENTION

The present disclosure generally relates to methods and systems for cleaning semiconductor substrates. In particular, the present disclosure is related to vapor-phase cleans for use in back-end-of-line processing of semiconductor substrates.

### BACKGROUND OF THE DISCLOSURE

Semiconductor device processes, e.g. back-end-of-line processes in particular, comprise the use of metal features such as interconnects. Exemplary metals that may be used include copper and cobalt. Some metals such as copper readily diffuse across a surface, which can cause metal contamination of active device regions, and it can hinder subsequent selective deposition processes.

For example, a back-end-of-line (BEOL) process may comprise a copper deposition step followed by a chemical mechanical polishing step (CMP). After the CMP there may be a queue time between CMP and next processing step. During this period, copper lines may be oxidized and oxidized copper may start to migrate on low k dielectric which is positioned between the copper lines. It can also complicate subsequent selective deposition processes.

Metal contamination of dielectrics such as low-k dielectrics can also be caused by imperfect selective depositions which can result in the formation of small metal grains or metal clusters on the dielectric.

Metal contaminants on dielectrics, caused e.g. by metal migration or imperfect selective deposition, may cause reliability, break down voltage, leakage current, and/or defect issues.

Thus there is a need for processes which allow avoiding metal contamination of dielectrics such as low-k dielectrics, and which facilitate selective depositions.

The following prior art documents are made of record: Mameli, Alfredo, et al. ACS nano 11.9 (2017): 9303-9311 describes an area-selective atomic layer deposition of SiO₂ using acetylacetone as a chemoselective inhibitor in an ABC-type cycle; Mameli, A., et al. ACS applied materials & interfaces 10.44 (2018): 38588-38595 describes isotropic atomic layer etching of ZnO using Acetylacetone and O₂ plasma; U.S. Pat. No. 9,991,138 describes an etching method and an etching apparatus; Zhao, Jing, Mahsa Konh, and Andrew Teplyakov. Applied surface science 455 (2018): 438-445 describes the surface chemistry of thermal dry etching of cobalt thin films using hexafluoroacetylacetone. U.S. Pat. No. 9,991,138 describes an etching method and an etching apparatus; D. Altieri et al., Journal of Vacuum Science & Technology A 35, 05C203 (2017) describes plasma-surface interactions at the atomic scale for patterning metals; U.S. Pat. No. 10,014,212 describes methods for selectively depositing metallic films.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to a method for cleaning a substrate comprising: providing a substrate comprising a dielectric and a metal surface to a reaction chamber; providing a cleaning agent to the reaction chamber, thereby contacting the substrate with the cleaning agent, and removing any oxidized metal contaminants from the substrate.

In some embodiments, the method comprises a step of providing an oxidizing agent to the reaction chamber before the step of providing the cleaning agent to the reaction chamber. Thus, further described is a method for cleaning a substrate. The method comprises providing a substrate comprising a dielectric and a metal surface, to a reaction chamber; providing an oxidizing agent to the reaction chamber, thereby contacting the substrate with the oxidizing agent and oxidizing any metal contaminants on the dielectric surface, thus forming oxidized metal contaminants; providing a cleaning agent to the reaction chamber, thereby contacting the substrate with the cleaning agent and removing the oxidized metal contaminants from the substrate.

In some embodiments, the method further comprises a step of providing a reducing agent to the reaction chamber before the step of providing an oxidizing agent to the reaction chamber. Thus, further described is a method for cleaning a substrate, the method comprising: providing a substrate comprising a dielectric and an oxidized metal surface to a reaction chamber; providing a reducing agent to the reaction chamber, thereby contacting the substrate with the reducing agent and converting the oxidized metal surface to a metal surface; providing an oxidizing agent to the reaction chamber, thereby contacting the substrate with the oxidizing agent and oxidizing any metal contaminants on the dielectric surface, thus forming oxidized metal contaminants; and, providing a cleaning agent to the reaction chamber, thereby contacting the substrate with the cleaning agent and removing the oxidized metal contaminants from the substrate.

In some embodiments, the reducing agent comprises an alcohol.

In some embodiments, the alcohol comprises an alkyl alcohol.

In some embodiments, the alkyl alcohol comprises ethanol.

In some embodiments, the oxidizing agent comprises an oxygen-comprising gas or gas mixture.

In some embodiments, the oxidizing agent comprises oxygen.

In some embodiments, the oxidizing agent a gas selected from O₂, O₃, H₂O, H₂O₂, and mixtures thereof.

In some embodiments, the oxidizing agent is selected from O₂, H₂O, and mixtures thereof.

In some embodiments, the oxidizing agent comprises an O₂ plasma.

In some embodiments, the step of providing the oxidizing agent to the reaction chamber and the step of providing the cleaning agent to the reaction chamber are repeated one or more times.

In some embodiments, the cleaning agent comprises a beta diketonate.

In some embodiments, the beta diketonate comprises hexafluoroacetylacetone (Hfac).

In some embodiments, the beta diketonate comprises acetylacetone (Hacac).

In some embodiments, the beta diketonate comprises dipivaloylmethane (Hthd).

In some embodiments, the cleaning agent comprises a cyclopentadienyl group.

In some embodiments, the cleaning agent comprises carbon monoxide.

In some embodiments, the cleaning agent comprises a carboxylic acid.

In some embodiments, the cleaning agent comprises formic acid.

In some embodiments, the step of providing a cleaning agent to the reaction chamber is followed by a step of providing a further oxidizing agent to the reaction chamber.

In some embodiments, the step of providing a further oxidizing agent to the reaction chamber comprises, in the following order, providing O₂ to the reaction chamber in an O₂ pulse and providing H₂O to the reaction chamber in a H₂O pulse.

In some embodiments, the O₂ pulse and the H₂O pulse are separated by a purge.

In some embodiments, the step of providing the cleaning agent to the reaction chamber and the step of providing the further oxidizing agent to the reaction chamber are separated by a purge.

In some embodiments, the step of providing a cleaning agent to the reaction chamber is followed by a step of providing a cleaning residue removal agent to the reaction chamber.

In some embodiments, the cleaning residue removal agent comprises an alcohol.

In some embodiments, the alcohol is an alkyl alcohol.

In some embodiments, the alkyl alcohol is selected from methanol, ethanol, isopropanol, and isobutanol.

In some embodiments, the cleaning residue removal agent comprises a further oxidizing agent.

In some embodiments, the step of providing a cleaning residue removal agent to the reaction chamber comprises, in the following order, providing O₂ to the reaction chamber in an O₂ pulse and providing H₂O to the reaction chamber in a H₂O pulse.

In some embodiments, the O₂ pulse and the H₂O pulse are separated by a purge.

In some embodiments, the step of providing the cleaning agent to the reaction chamber and the step of providing the cleaning residue removal agent to the reaction chamber are separated by a purge.

In some embodiments, the step of providing a cleaning residue removal agent to the reaction chamber comprises a first sub step and a second sub step. The first sub step comprises providing an alcohol to the reaction chamber, and the second sub step comprises providing an oxidizing agent to the reaction chamber.

In some embodiments, the alcohol is an alkyl alcohol.

In some embodiments, the oxidizing agent is an oxygen-containing gas or gas mixture.

In some embodiments, the method further comprises a step of purging the reaction chamber after the substrate has been contacted with the cleaning agent.

In some embodiments, the step of providing the reducing agent to the reaction chamber and the step of providing the oxidizing agent to the reaction chamber are separated by a purge.

In some embodiments, the step of providing the oxidizing agent to the reaction chamber and the step of providing the cleaning agent to the reaction chamber are separated by a purge.

In some embodiments, the method does not involve the use of a plasma in the reaction chamber.

In some embodiments, the method further comprises, after the cleaning agent has been provided to the reaction chamber, a step of exposing the surface to a plasma.

In some embodiments, the plasma is selected from a H₂ plasma, a N₂/H₂ plasma, an N₂/Ar plasma, an N₂ plasma, and an NH₃ plasma.

In some embodiments, the steps of providing the cleaning agent to the reaction chamber and the step of exposing the surface to a plasma are separated by a purge.

In some embodiments, the substrate comprises monocrystalline silicon.

In some embodiments, the dielectric surface comprises a low-k dielectric.

In some embodiments, the metal surface comprises a Co surface.

In some embodiments, the method is carried out at a temperature of at least 100° C. to at most 300° C.

In some embodiments, the metal surface comprises Co and the dielectric surface comprises Co contaminants.

In some embodiments, the metal surface comprises Cu and the dielectric surface comprises Cu contaminants.

In some embodiments, the metal surface comprises a plurality of metal lines which are spaced less than 30 nm apart.

Further described is a method for selectively depositing a material on a substrate comprising a metal surface and a dielectric surface, the method comprising the steps: cleaning the substrate by means of a method as described herein; and, selectively depositing the material on one of the metal surface and the dielectric surface.

In some embodiments, the material comprises a metal, and the metal is deposited on the metal surface.

In some embodiments, the metal comprises Co.

In some embodiments, the material comprises a polymer.

In some embodiments, the material comprises a dielectric.

Further described is a system comprising one or more reaction chambers, a cleaning gas source, and a controller. In such embodiments, the controller is configured for causing the system to carry out a method as disclosed herein.

In some embodiments, the system further comprises an oxidizing agent source. Also, in such embodiments, the controller is configured for causing the system to bring oxidizing agent from the oxidizing agent source to a reaction chamber.

In some embodiments, the system further comprises a plasma gas source and a plasma generator. In such embodiments, the controller is configured for causing the system to bring oxidizing agent from the plasma gas source to a reaction chamber. Also, the controller is configured for actuating the plasma generator.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

A more complete understanding of exemplary embodiments of the present disclosure can be derived by referring to the detailed description and claims when considered in connection with the following illustrative figures.

FIG. 1 illustrates various stages of a substrate undergoing a process according to an exemplary embodiment of this disclosure.

FIG. 2 illustrates a system according to an embodiment of this disclosure.

FIG. 3 illustrates a method according to an embodiment of this disclosure.

FIG. 4 illustrates a method according to an embodiment of this disclosure.

Throughout the figures, the following numbering is adhered to: 100—substrate; 110—monocrystalline silicon; 120—metal layer; 125—metal surface; 130—dielectric layer; 140—metal contaminants; 200—system; 202—one or more reaction chambers; 204—oxidizing agent gas source; 206—cleaning agent gas source; 208—purge gas source; 210—exhaust; 212—controller; 214—218—lines; 300—method; 310—step of providing a substrate to a reaction chamber; 320—step of providing a reducing agent to the reaction chamber; 325—step of purging the reaction chamber; 330—step of providing an oxidizing agent to the reaction chamber; 335—step of purging the reaction chamber; 340—step of providing a cleaning agent to the reaction chamber; 345—step of purging the reaction chamber; 350—step of providing a further oxidizing agent to the reaction chamber; 355—step of purging the reaction chamber; 360—end; 400—method; 410—step of providing a substrate to a reaction chamber; 420—step of providing a reducing agent to the reaction chamber; 425—step of purging the reaction chamber; 430—step of providing an oxidizing agent to the reaction chamber; 435—step of purging the reaction chamber; 440—step of providing a cleaning agent to the reaction chamber; 445—step of purging the reaction chamber; 450—step of providing a cleaning residue removal agent to the reaction chamber; 455—step of purging the reaction chamber; 460—end.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood that the invention extends beyond the specifically disclosed embodiments and/or uses thereof and obvious modifications and equivalents thereof. Thus, it is intended that the scope of the invention disclosed should not be limited by the particular disclosed embodiments described below.

The present disclosure generally relates to methods and devices for cleaning a substrate.

As used herein, the term “substrate” may refer to any underlying material or materials including and/or upon which one or more layers can be deposited. A substrate can include a bulk material, such as silicon (e.g., single-crystal silicon), other Group IV materials, such as germanium, or other semiconductor materials, such as Group II-VI or Group III-V semiconductor materials. A substrate can include can include a stack of one or more layers overlying a bulk material. Further, the substrate can additionally or alternatively include various features, such as recesses, lines, and the like formed within or on at least a portion of a layer of the substrate. The presently described methods are particularly suitable for cleaning substrates comprising a metal surface and a dielectric surface, i.e. for substrates comprising exposed metal areas and exposed dielectric areas.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, “gas” may include material that is a gas at standard conditions, a vaporized solid and/or a vaporized liquid, and may comprise a single gas or a mixture of gases, depending on the context. A gas other than the process gas, i.e., a gas introduced without passing through a gas distribution assembly, such as a showerhead, other gas distribution device, or the like, may be used for, e.g., sealing the reaction space, and may include a seal gas, such as a rare gas.

As used herein, the term “purge” may refer to a procedure in which an inert or substantially inert gas is provided to a reactor chamber in between two pulses of gasses which react with each other. For example, a purge, e.g. using nitrogen gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied. Suitable purge gasses include substantially inert gasses such as noble gasses, e.g. He, Ne, Ar, Xe, Kr, etc. . . .

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In accordance with aspects of the disclosure, any defined meanings of terms do not necessarily exclude ordinary and customary meanings of the terms.

Described herein is a method for cleaning a substrate. The substrate comprises two different areas. In other words, the substrate comprises two different surfaces. In particular, the substrate includes a dielectric surface and a metal surface. The dielectric surface comprises metal contaminants. The metal contaminants, may, for example have reached the dielectric surface through surface diffusion from the metal surface. Alternatively, the metal contaminants may have been deposited on the dielectric surface in an imperfect selective deposition process. Alternatively, the metal contaminants may have been deposited on the dielectric surface during a chemical mechanical polishing (CMP) step. The metal contaminants may comprise, for example, a copper-containing material, e.g. copper or copper oxide particles on a dielectric such as a low-k dielectric. The methods described herein comprise providing the substrate to a reaction chamber. It shall be understood that “metal surface” refers to a surface of a metal layer comprised in the substrate. Similarly, it shall be understood that “dielectric surface” refers to a surface of a dielectric layer comprised in the substrate.

The presently described methods may comprise providing an oxidizing agent to the reaction chamber. Thus, the substrate is contacted with the oxidizing agent and the metal contaminants are oxidized to form oxidized metal contaminants. This step is particularly useful when the metal contaminants on the dielectric surface are in a metallic state, i.e. non-oxidized state. However, when the substrate comprises oxidized metal contaminants, which can occur when the substrate has been exposed to atmospheric air, the step of providing an oxidizing agent to the reaction chamber may be omitted.

Optionally, contacting the substrate with an oxidizing agent is preceded by providing a reducing agent to the reaction chamber, thereby contacting the substrate with the reducing agent. This can be especially useful when substrates such as wafers are used which comprise an oxidized metal surface, also called an oxidized metal surface layer. Oxidized metal comprised in the oxidized metal surface can thus be reduced to form metal, thereby converting the oxidized metal surface to a metal surface. Such embodiments can be applied to substrates which were oxidized in uncontrolled conditions, for example, oxidized in atmospheric air, e.g. while in a waiting queue which can result in formation of a metal oxide skin having an unknown and variable thickness. Such a metal skin with uncontrolled thickness formed on e.g. an interconnect line, can be removed during a subsequent step of exposing the substrate to a cleaning agent, thereby recessing, i.e. removing material from, the interconnect line in an uncontrolled way, which can result, for example, in reliability issues. Conversely, a sequence of a first step of exposing the substrate to a reducing agent and a second step of exposing the substrate to an oxidizing agent can suitably result in the formation of an oxidized metal layer having a controlled thickness, e.g. a thickness of at least 1.0 to at most 5.0 nm, which can then be removed in a controlled way during a subsequent cleaning step. In some embodiments, the reducing agent comprises an alcohol. Suitable alcohols include alkyl alcohols such as ethanol or isopropyl alcohol. In some embodiments, the step of providing the reducing agent to the reaction chamber comprises generating a H₂ plasma in the reaction chamber, thereby exposing the substrate to the H₂ plasma. In other words, in some embodiments, the reducing agent comprises a H₂ plasma. In some embodiments, the step of providing the reducing agent to the reaction chamber and the step of providing the oxidizing agent to the reaction chamber are separated by a purge. Alternatively, the step of providing the reducing agent to the reaction chamber may directly precede the step of providing the oxidizing agent to the reaction chamber. In other words, and in some embodiments, no purge step occurs between the steps of providing the reducing agent to the reaction chamber and providing the oxidizing agent to the reduction agent.

The method comprises a step of providing a cleaning agent to the reaction chamber. Accordingly, the substrate is contacted with the cleaning agent and the oxidized metal contaminants are removed from the substrate. Suitably, the cleaning agent reacts with the oxidized metal contaminants to form volatile species, which are then removed from the substrate. Thus oxidized metal contaminants, e.g. atom clusters comprising metal-oxygen bonds, may be effectively cleaned and removed from the dielectric surface. Advantageously, metal interconnects such as copper-containing interconnects can be left substantially unaffected by the cleaning method. Indeed, whereas the oxidizing agent can act to fully oxidize metal contaminants, which are generally very small, it does not substantially affect larger metal features such as copper interconnects; at most the surface of such features is oxidized, and at most the oxidized surface is removed by the cleaning agent, along with the oxidized metal contaminants.

In some embodiments, the step of providing a cleaning agent to the reaction chamber comprises a plurality of cleaning sub-cycles. A cleaning sub-cycle comprises a cleaning pulse in which cleaning agent is provided to the reaction chamber, and a purge pulse in which a purge gas is provided to the reaction chamber. Suitable cleaning agents include beta-diketonates. Suitable cleaning agents include halogen-containing compounds. Suitable cleaning agents include halogen-containing beta-diketonates. Suitable cleaning agents include fluorine-containing beta-diketonates. Suitable cleaning agents include hexafluoroacetylacetone. Suitable cleaning agents include carboxylic acids such as formic acid or ethanoic acid. In some embodiments, the step of providing a cleaning agent to the reaction chamber comprises from at least 2 to at most 50 cleaning sub-cycles, or from at least 3 to at most 20 cleaning sub-cycles, or from at least 4 to at most 10 cleaning sub-cycles. Using a plurality of cleaning sub-cycles can advantageously improve cleaning efficiency.

Cleaning a substrate by means of a method according to an embodiment of the present disclosure can, for example, increase performance of electronic devices manufactured in the substrate. Additionally or alternatively, it may enhance subsequent selective depositions relying in differences in surface chemistry between the dielectric surface and the metal surface. It shall be understood that the oxidizing agent may also oxidize the metal surface. The cleaning agent then removes the oxidized metal surface along with the metal contaminants. This notwithstanding, only a very small amount of material is removed from the metal surface in this way, e.g. less than a nm of metal, or less than a monolayer of metal. Also, it shall be understood that during the present methods for cleaning a substrate, the dielectric surface is substantially unaffected, except that the contaminants are removed from its surface.

In some embodiments, the oxidizing agent includes an oxygen-containing compound or gas mixture. Suitable oxidizing agents include H₂O, H₂O₂, O₂, O₃, N₂O, and mixtures thereof. Particularly good results may be obtained with H₂O and H₂O₂. In some embodiments, atmospheric air is used as an oxidizing agent. These oxidizing agents may be allowed to react thermally, i.e. without the use of a plasma. Alternatively, a plasma may be maintained in the reaction chamber while the oxidizing agent is provided to the reaction chamber. One example of a plasma-based oxidizing treatment is the application of an O₂ plasma.

Optionally, the step of providing the oxidizing agent to the reaction chamber and the step of providing the cleaning agent to the reaction chamber are repeated one or more times. This can be useful, for example, to remove a large amount of metal contamination from the dielectric surface.

Various cleaning agents may be suitable. For example, the cleaning agent may comprise a beta diketonate such as hexafluoroacetylacetone (Hfac), acetylacetone (Hacac), or dipivaloylmethane, i.e. 2,2,6,6-tetramethyl-3,5-heptanedione (Hthd). Alternatively, the cleaning agent may comprise a cyclopentadienyl group, such as a substituted or unsubstituted cyclopentadienyl group. Exemplary substituted cyclopentadienyl groups comprise alkyl-substituted cyclopentadienyl groups such as methyl-substituted cyclopentadienyl, ethyl-substituted cyclopentadienyl, isopropyl-substituted cyclopentadienyl, and isobutyl-substituted cyclopentadienyl. Alternatively, the cleaning agent may comprise a carbonyl group. In some embodiments, the cleaning agent comprises carbon monoxide. In some embodiments, the cleaning agent comprises cyclopentadiene. In some embodiments, the cleaning agent comprises a mixture of one or more cyclopentadienyl-containing compounds on the one hand and one or more carbonyl-containing compounds on the other hand. In some embodiments, the cleaning agent consists of a mixture of cyclopentadiene and carbon monoxide.

In some embodiments, the cleaning agent comprises a β-ketoamine, for example acetylacetonamine or 4-amino-1,1,1,5,5,5-hexafluoropentane-2-one.

In some embodiments, the cleaning agent comprises a β-dithione or a β-dithioketone. An exemplary β-dithione is 1,1,1,5,5,5-hexafluoropentane-2,4-dithione.

In some embodiments, the cleaning agent comprises a β-diimine. An exemplary β-diimine is 1,1,1,5,5,5-hexafluoropentane-2,4-diimine.

In some embodiments, the cleaning agent comprises an amino thione, e.g. a compound comprising a thione group and an amine group at a beta position. Exemplary amino thiones include 4-amino-3-pentene-2-thione and 4-amino-1,1,1,5,5,5-hexafluoropentane-2-thione.

In some embodiments, the cleaning agent comprises a β-thione imine. In some embodiments, the cleaning agent comprises a β-thioketone imine. Suitable β-thione imines include 1,1,1,5,5,5-hexafluoropentane-2-thione-4-imine.

In some embodiments, the cleaning agent comprises a carboxylic acid. Suitable carboxylic acids include formic acid.

In some embodiments, the cleaning agent can be provided to the reaction chamber as a mixture comprising the cleaning agent and H₂. For example, the cleaning agent can be provided to the reaction chamber in a gas stream comprising from at least 10 volume % (vol. %) H₂ to at most 90 vol. % H₂, or from at least 10 vol. % H₂ to at most 30 vol. % H₂, or from at least 30 vol. % H₂ to at most 50 vol. % H₂, or from at least 50 vol. % H₂ to at most 70 vol. % H₂, or from at least 70 vol. % H₂ to at most 90 vol. % H₂.

In some embodiments, the cleaning agent can be provided to the reaction chamber as a mixture comprising the cleaning agent and CO₂. For example, the cleaning agent can be provided to the reaction chamber in a gas stream comprising from at least 10 volume % (vol. %) CO₂ to at most 90 vol. % CO₂, or from at least 10 vol. % CO₂ to at most 30 vol. % CO₂, or from at least 30 vol. % CO₂ to at most 50 vol. % CO₂, or from at least 50 vol. % CO₂ to at most 70 vol. % CO₂, or from at least 70 vol. % CO₂ to at most 90 vol. % CO₂.

In some embodiments, the cleaning agent can be provided to the reaction chamber in a gas stream comprising from at least 10 volume % (vol. %) cleaning agent to at most 90 vol. % cleaning agent, or from at least 10 vol. % cleaning agent to at most 30 vol. % cleaning agent, or from at least 30 vol. % cleaning agent to at most 50 vol. % cleaning agent, or from at least 50 vol. % cleaning agent to at most 70 vol. % cleaning agent, or from at least 70 vol. % cleaning agent to at most 90 vol. % cleaning agent. The remainder of the gas stream can comprise a further gas. Exemplary further gasses include H₂ and CO₂.

Providing the cleaning agent to the reaction chamber mixed with a further gas such as H₂ and CO₂ can advantageously prevent re-deposition of metal contaminants after they have been removed from the substrate using the cleaning agent. The further gas may be a decomposition product of the cleaning agent. Without the presently disclosed methods or devices being limited to any particular theory or mode of operation it is believed that, when formic acid is used as a cleaning agent, e.g. at a temperature of from at least 150° C. to at most 250° C., or at a temperature of at least 170° C. to at most 230° C., formic acid may spontaneously decompose into H₂ or CO₂ during the cleaning step. By mixing formic acid with one or more of its decomposition products, i.e. H₂ and CO₂, it is believed that the decomposition of formic acid may be slowed down or prevented, thereby improving cleaning uniformity.

In an exemplary embodiment, Hfac was used for removing oxidized metal contaminants from a substrate comprising Co-capped Cu lines, i.e. interconnect lines comprising copper covered by cobalt. The substrate further comprises a low-k dielectric in which the Co-capped Cu lines are embedded. The clean was performed at 200° C. XPS measurements showed that oxidized metal contaminants were removed from the substrate, while not substantially removing Co or Cu from the Co-capped Cu lines.

The method may further comprise a step of purging the reaction chamber after the substrate has been contacted with the cleaning agent. For example when Hfac is used as a cleaning agent, a purge step can be useful for removing volatile species such as copper hexafluoroacetylacetonate or cobalt hexafluoroacetylacetonate from the substrate.

Also, the method may further comprise, after the cleaning step, providing a plasma in the reaction chamber to expose the substrate and its surfaces to a plasma. Optionally, the substrate may be exposed to the plasma after the reaction chamber has been purged. Suitable plasmas include a H₂ plasma, an N₂/H₂ plasma, an N₂/Ar plasma, an N₂ plasma, am H₂/Ar plasma, an N₂/H₂ plasma, N₂/Ar, and an NH₃ plasma. In some embodiments, the plasma is selected from the list consisting of a H₂/Ar plasma, a N₂/H₂ plasma, and a N₂/Ar plasma. This can be useful, for example, when the step of contacting the substrate with the cleaning agent leaves a residual material on the dielectric and/or metal surface of the substrate. For example, when Hfac is used as a cleaning agent, a carbon-fluorine rich layer may be formed on the dielectric surface, and metal fluorides may be formed on the metal surface. Such residual materials can then be adequately removed with any one of a H₂ plasma, an N₂/H₂ plasma, an N₂/Ar plasma, an N₂ plasma, or an NH₃ plasma. It shall be understood that a H₂ plasma refers to a plasma that employs H₂ as a plasma gas. It therefore comprises H₂ and/or reactive species derived thereof. Similarly, an N₂/H₂ plasma refers to a plasma that employs a mixture of N₂/H₂ as a plasma gas, an N₂/Ar plasma refers to a plasma that employs a mixture of N₂ and Ar as a plasma gas, an N₂ plasma refers to a plasma that employs N₂ as a plasma gas, and an NH₃ plasma refers to a plasma that employs NH₃ as a plasma gas. The plasma can suitably remove surface contaminants remaining on the dielectric surface after application of the cleaning agent. Exemplary surface contaminants that may be removed by means of the plasma include metal fluorides and a carbon-fluorine rich layer.

In some embodiments, the step of providing the cleaning agent to the reaction chamber and the step of exposing the surface of the substrate to a plasma are separated by a purge. In other words, in some embodiments, the step of providing the cleaning agent to the reaction chamber and the step of providing a plasma in the reaction chamber to expose the substrate and its surfaces to a plasma may be separated by a purge.

In some embodiments, the step of providing a cleaning agent to the reaction chamber is followed by a step of providing a further oxidizing agent to the reaction chamber, thereby exposing the substrate to the oxidizing agent and re-oxidizing the metal surface. The step of providing a cleaning agent to the reaction chamber may be performed as an alternative to, or in addition to, the step of providing a plasma to the reaction chamber. Providing a further oxidizing agent to the reaction chamber can suitably remove etching residues such as For F-containing compounds from the substrate's surface. Additionally or alternatively, the step of providing a further oxidizing agent to the reaction chamber can be used as a surface conditioning step prior to a subsequent selective deposition step.

In some embodiments, the step of providing a further oxidizing agent to the reaction chamber comprises, in the following order, providing O₂ to the reaction chamber in an O₂ pulse and providing H₂O to the reaction chamber in a H₂O pulse. In some embodiments, the O₂ pulse and the H₂O pulse are separated by a purge. Such a pulsing sequence can result in a particularly reproducible oxidation, and a desirable OH termination on the resulting oxidized metal surface.

In some embodiments, the step of providing the cleaning agent to the reaction chamber and the step of providing the further oxidizing agent to the reaction chamber are separated by a purge.

In some embodiments, the presently described methods do not employ a plasma. In other words, in some embodiments, all steps comprised in the present methods are thermal. Thus, in such embodiments, neither the step of providing a reducing agent to the reaction chamber, the step of providing an oxidizing agent to the reaction chamber, the step of providing a cleaning agent to the reaction chamber, the step of providing a further oxidizing agent, or a cleaning residue removal agent, to the reaction chamber, nor any of the purges used during the method involve using a plasma. This can be useful when the substrate comprises layers or structures that are susceptible to plasma damage. In other words, avoiding the use of a plasma can be an effective way of avoiding plasma damage.

In some embodiments, the step of providing a cleaning agent to the reaction chamber is followed by a step of providing a cleaning residue removal agent to the reaction chamber. Exemplary cleaning residue removal agents include alcohols. Suitable alcohols include linear, cyclic, or branched alkyl and alkenyl alcohols. Suitable alkyl alcohols include methanol, ethanol, and isopropanol. Suitable cleaning residue agents further comprise carboxylic acids such as formic acid and ethanoic acid. Thus, good cleaning efficiency and excellent process uniformity can be obtained. It shall also be noted that alcohols can advantageously remove fluorine surface residues when a fluorine-containing cleaning agent such as hexafluoroacetylacetone is used.

In some embodiments, the step of providing a cleaning residue removal agent comprises a first sub step and a second sub step. The first sub step comprises providing an alcohol to the reaction chamber. Suitable alcohols include linear, cyclic, or branched alkyl and alkenyl alcohols. Suitable alkyl alcohols include methanol, ethanol, and isopropanol. The second sub step comprises providing an oxidizing agent to the reaction chamber. Suitable oxidizing agents include oxygen-containing gasses and oxygen-containing gas mixtures. In some embodiments, the oxidizing agent is O₂. In some embodiments, the first and second sub step are separated by a purge. Thus, good cleaning efficiency and excellent process uniformity can be obtained.

In some embodiments, the dielectric surface comprises a low-k dielectric. Examples of low-k dielectrics include SiOC, SiOCN, and the like. Alternatively, the dielectric surface may comprise SiO₂, SiN, SiCN, SiC, and/or a high-k dielectric such as HfO₂, ZrO₂, Al₂O₃, and the like.

In some embodiments, the metal surface comprises a metal such as Cu, Co, Al, and W. The present methods are particularly suitable for cleaning substrates comprising a Co surface, in which the dielectric surface comprises Co contaminants. In other embodiments, the metal surface comprises Cu, and the dielectric surface comprises Cu contaminants. The metal surface can, for example, comprise a plurality of metal lines which are spaced less than 30 nm apart, e.g. spaced from at least 5 nm apart to at most 10 nm apart, or spaced from at least 10 nm apart to at most 20 nm apart, or spaced from at least 20 nm apart to at most 30 nm apart.

In some embodiments, the method is carried out at a temperature of at least 100° C. to at most 300° C. In an advantageous embodiment, the cleaning agent comprises a beta diketonate such as Hfac, and the substrate is contacted with the cleaning agent at a temperature of at least 150° C. to at most 250° C., for example at a temperature of 200° C.

Further disclosed is a method for selectively depositing a material on a substrate. The substrate can be a substrate as described herein and comprises a metal surface and a dielectric surface. The method comprises a step of cleaning the substrate by means of a method as described herein and a step of selectively depositing the aforementioned material on one of the metal surface or the dielectric surface. It shall be understood that suitable deposition processes capable of selectively depositing a material on a dielectric surface versus a metal surface or vice versa are known per se. By performing a clean as described herein before selective deposition, the selectivity of the deposition process can be improved. In a preferred embodiment, surface cleaning and selective deposition are performed in one and the same reaction chamber, or in a single system comprising more than one reaction chamber, without an intermediate air break.

In some embodiments, the material which is selectively deposited comprises a metal, and the metal is deposited on the metal surface. Exemplary metals that can be deposited include Cu, Co, Ti, W, Ru, Mo, and Al.

In some embodiments, the material which is deposited comprises a polymer. Suitable polymers that may be selectively deposited include polyamides and polyimides.

In some embodiments, the material which is deposited comprises a dielectric. Suitable dielectrics that may be deposited include silicon oxide, low-k dielectrics such as SiOCN, SiOC, SiN, SiCN, BN, and high-k dielectrics such as HfO₂, ZrO₂, and Al₂O₃.

In some embodiments, the substrate on which the material is selectively deposited comprises a critical dimension, e.g. a line width, of less than 50 nm, of less than 40 nm, of less than 30 nm, of less than 20 nm, or of less than 10 nm.

Further described is a system comprising one or more reaction chambers. The system further comprises a cleaning gas source and a controller. The controller is configured for causing the system to carry out a method as described herein. In some embodiments, the system further comprises an oxidizing agent source and the controller is configured causing the system to bring the oxidizing agent from the oxidizing agent source to a reaction chamber.

In some embodiments, the system further comprises a plasma gas source and a plasma generator, and the controller is configured for causing the system to bring oxidizing agent from the plasma gas source to a reaction chamber. In such embodiments, the controller is further configured for actuating the plasma generator.

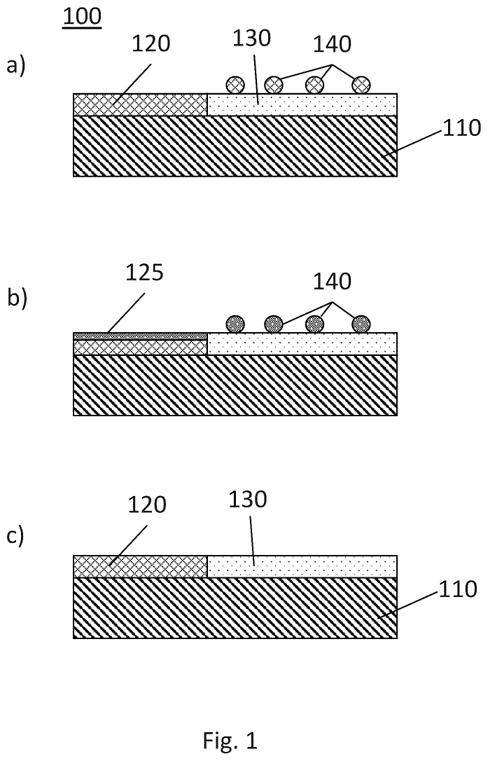

In an exemplary embodiment, reference is made to FIG. 1. FIG. 1 shows an exemplary substrate (100), not to scale, undergoing an embodiment of the methods described herein. In panel a) the substrate (100) is in an as-delivered state. It comprises monocrystalline silicon (110), a metal layer (120) comprising a metal surface, a dielectric layer (130) comprising a dielectric surface, and metal contaminants (140) positioned on the dielectric surface.

In panel b), the substrate is shown after exposure to an oxidizing agent: the metal layer now comprises an oxidized metal surface (125), which is generally very thin, e.g. a monolayer, or 0.5 to 5.0 nm, or 1.0 to 2.0 nm thick. The metal contaminants are now fully oxidized, i.e. exposure to the oxidizing agent turned them into oxidized metal contaminants (140). Note that the substrate can also be delivered in an oxidized state as shown in panel b), thus obviating the need for exposing the surface to an oxidizing agent.

In panel c), the substrate is shown after exposure to a cleaning agent which removes the oxidized metal surface and the oxidized metal contaminants, thus leaving a cleaned substrate comprising a cleaned metal surface and a cleaned dielectric surface.

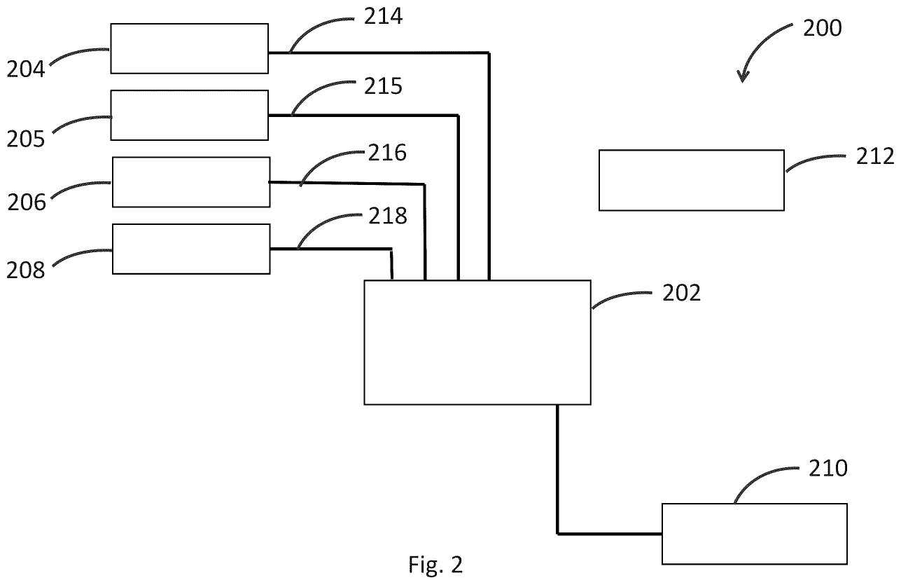

FIG. 2 illustrates a system (200) in accordance with further exemplary embodiments of the disclosure. The system (200) can be used to perform a method as described herein and/or form a structure or device portion as described herein.

In the illustrated example, the system (200) includes one or more reaction chambers (202), an optional oxidizing agent gas source (204), a cleaning agent gas source (206), a purge gas source (208), an exhaust (210), and a controller (212). Optionally, the system further comprises a plasma gas source, and a plasma generator (both not shown).

The reaction chamber (202) can include any suitable reaction chamber, such as an ALD or CVD reaction chamber.

The oxidizing agent gas source (204) can include a vessel and one or more oxidizing agents as described herein-alone or mixed with one or more carrier (e.g., inert) gases. The cleaning agent gas source (206) can include a vessel and one or more cleaning agents as described herein-alone or mixed with one or more carrier gases. The purge gas source (208) can include one or more inert gases as described herein. Although illustrated with four gas sources (204)-(208), the system (200) can include any suitable number of gas sources. For example the system can further comprise a plasma gas source, along with a plasma generator. The gas sources (204)-(208) can be coupled to reaction chamber (202) via lines (214)-(218), which can each include flow controllers, valves, heaters, and the like. Additionally or alternatively, the system can comprise a reducing agent gas source and/or a further oxidizing agent gas source. If present, the reducing agent gas source (not shown) can include a vessel comprising one or more reducing agents. Alternatively, the reducing agent gas source can include a gas line carrying one or more reducing agents. If present, the oxidizing agent gas source can comprise a vessel comprising one or more further oxidizing agents. Alternatively, the oxidizing agent gas source can comprise a gas line carrying one or more further oxidizing agents.

The exhaust (210) can include one or more vacuum pumps.

The controller (212) includes electronic circuitry and software to selectively operate valves, manifolds, heaters, pumps and other components included in the system (200). Such circuitry and components operate to introduce precursors, reactants, and purge gases from the respective sources (204)-(208). The controller (212) can control timing of gas pulse sequences, temperature of the substrate and/or reaction chamber, pressure within the reaction chamber, and various other operations to provide proper operation of the system (200).

The controller (212) can include control software to electrically or pneumatically control valves to control flow of reducing agents, oxidizing agents, further oxidizing agents, cleaning agents, plasma gasses, and/or purge gases into and out of the reaction chamber (202). The controller (212) can include modules such as a software or hardware component, e.g., a FPGA or ASIC, which performs certain tasks. A module can advantageously be configured to reside on the addressable storage medium of the control system and be configured to execute one or more processes.

Other configurations of the system (200) are possible, including different numbers and kinds of oxidation agent sources, cleaning agent sources, plasma gas sources, and purge gas sources. Further, it will be appreciated that there are many arrangements of valves, conduits, oxidation agent sources, cleaning agent sources, plasma gas sources, and purge gas sources that may be used to accomplish the goal of feeding gases into the reaction chamber (202). Further, as a schematic representation of a system, many components have been omitted for simplicity of illustration, and such components may include, for example, various valves, manifolds, purifiers, heaters, containers, vents, and/or bypasses.

During operation of the system (200), substrates, such as semiconductor wafers (not illustrated), are transferred from, e.g., a substrate handling system, to the reaction chamber (202). Once substrate(s) are transferred to the reaction chamber (202), one or more gases from the gas sources (204)-(208), such as precursors, reactants, carrier gases, and/or purge gases, are introduced into reaction chamber (202).

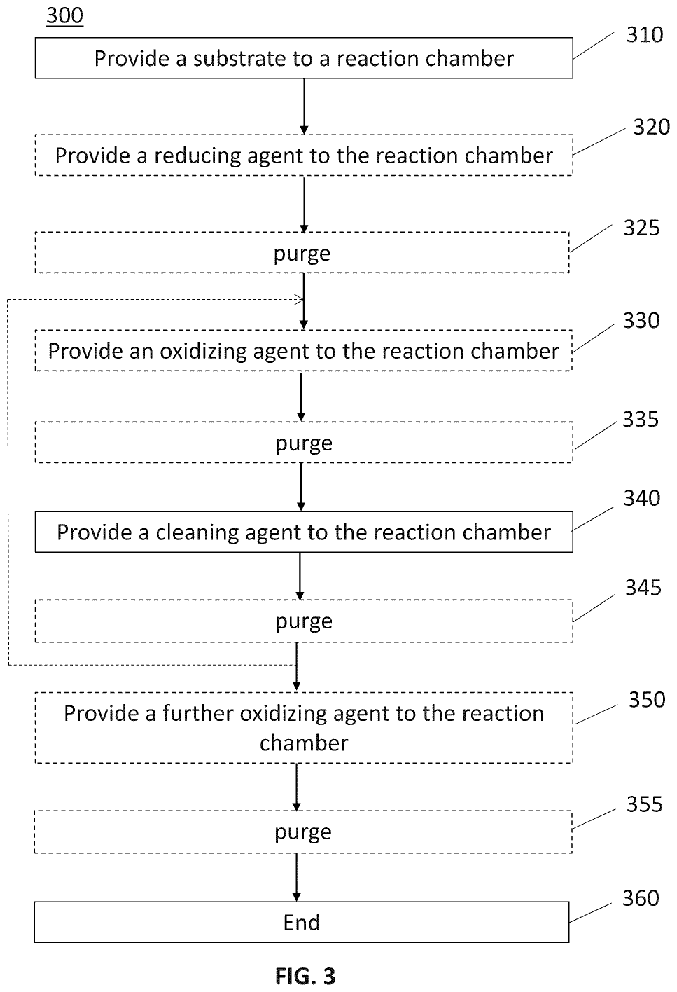

By way of a further example, reference is made to FIG. 3 which shows an embodiment of a method (300) as described herein. Suitably, the method can be carried out at a temperature of at least 100° C. to at most 300° C., or at a temperature of at least 150° C. to at most 250° C., or at a temperature of 200° C. The method comprises a step of providing a substrate to a reaction chamber (310). Then, the method may comprise an optional step of providing a reducing agent to the reaction chamber (320). Then, the method may comprise an optional step of purging the reaction chamber (325). Then, the method may comprise an optional step of providing an oxidizing agent to the reaction chamber (330). Then, the method may comprise an optional step of purging the reaction chamber (335). Then, the method comprises a step of providing a cleaning agent to the reaction chamber (340). Then, the method may comprise an optional step of purging the reaction chamber (345). Optionally, the step of providing the oxidizing agent to the reaction chamber (330) and the step of providing the cleaning agent to the reaction chamber (340) may be repeated one or more times. Then, the method may comprise an optional step of providing a further oxidizing agent to the reaction chamber (350). Then, the method may comprise an optional step of purging the reaction chamber (355), whereafter the method ends (360).

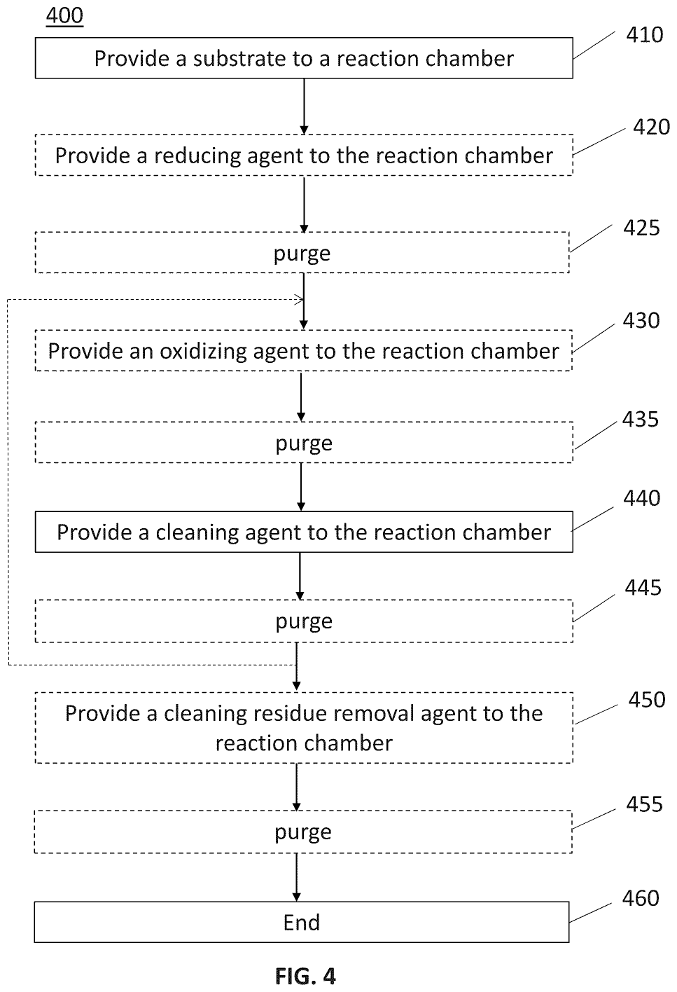

In an exemplary embodiment, an embodiment of a process according to FIG. 4 is described. Suitably, the process can be carried out at a temperature of at least 100° C. to at most 300° C., or at a temperature of at least 150° C. to at most 250° C., or at a temperature of 200° C. In this embodiment, the method comprises a step of providing a reducing agent to the reaction chamber (420). A suitable reducing agent comprises an alkyl alcohol such as methanol, ethanol, or isopropanol. In one preferred embodiment, ethanol is used as an alkyl alcohol. Then, the reaction chamber is purged (425), for example for a duration of at least 1 second to at most 5 seconds. Then, the method comprises a step of providing an oxidizing agent to the reaction chamber (430). Suitable oxidizing agents include oxygen-containing gasses or gas mixtures. One suitable oxidizing agent is O₂. Then, the method comprises a step of purging the reaction chamber (435). Then, the method comprises a step of providing a cleaning agent to the reaction chamber (440). Suitable cleaning agents include beta diketonates such as hexafluoroacetylacetone. Then, the reaction chamber is purged (445). In some embodiments, the step of providing a cleaning agent to the reaction chamber suitably comprises a plurality of cleaning sub-cycles, a cleaning sub-cycle comprising a cleaning pulse in which cleaning agent is provided to the reaction chamber, and a purge pulse in which a purge gas is provided to the reaction chamber. In some embodiments, the step of providing a cleaning agent to the reaction chamber comprises from at least 2 to at most 20 cleaning sub-cycles, or from at least 3 to at most 10 cleaning sub-cycles. After the step of providing a cleaning agent to the reaction chamber, the method comprises a step of providing a cleaning residue removal agent to the reaction chamber (450). Exemplary cleaning residue removal agents include alcohols, for example alkyl alcohols. A suitable cleaning residue removal agent is ethanol. Then, the method ends (460). In some embodiments, one or more process steps can be carried out at a temperature which is different from the temperature at which one or more other process steps are carried out. Thus, in some embodiments, one or more steps are carried out at a first temperature, and one or more steps are carried out at a second temperature. For example, in some embodiments, the steps of providing a reducing agent to the reaction chamber (420), the step of providing a cleaning agent to the reaction chamber (440), and the step of providing a cleaning residue removal agent to the reaction chamber (450) can be carried out at a first temperature; and, the step of providing an oxidizing agent to the reaction chamber (430) can be carried out at a second temperature. In some embodiments, the first temperature is different than the second temperature. In some embodiments, the first temperature is higher than the second temperature. In some embodiments, the first temperature is lower than the second temperature. In some embodiments, the first temperature is from at least 5° C. to at most 50° C. higher than the second temperature. In some embodiments, the first temperature is from at least 10° C. to at most 20° C. higher than the second temperature. In some embodiments, the first temperature is from at least 5° C. to at most 50° C. lower than the second temperature. In some embodiments, the first temperature is from at least 10° C. to at most 20° C. lower than the second temperature. In exemplary embodiments, the first temperature is 200° C. and the second temperature is 190° C. In exemplary embodiments, the first temperature is 190° C. and the second temperature is 200° C.

In an exemplary embodiment, an embodiment of a process according to FIG. 4 is described. In this embodiment, the method comprises a step of providing a reducing agent to the reaction chamber (420). A suitable reducing agent comprises an alkyl alcohol such as methanol, ethanol, or isopropanol. In one preferred embodiment, ethanol is used as an alkyl alcohol. Then, the reaction chamber is purged (425). Then, the method comprises a step of providing an oxidizing agent to the reaction chamber (430). Suitable oxidizing agents include oxygen-containing gasses or gas mixtures. One suitable oxidizing agent is O₂. Then, the method comprises a step of purging the reaction chamber (435). Then, the method comprises a step of providing a cleaning agent to the reaction chamber (440). Suitable cleaning agents include beta diketonates such as hexafluoroacetylacetone. Beta diketonates such as hexafluoroacetylacetone can be suitably used at a substrate temperature of at least 100° C. to at most 300° C., for example at a temperature of at least 100° C. to at most 250° C., for example at a temperature of 200° C. Then, the reaction chamber is purged (445). None of the method steps are repeated in this exemplary embodiment. Then, the method comprises a step of providing a cleaning residue removal agent to the reaction chamber (450). The step of providing a cleaning residue removal agent suitably comprises a first sub step and a second sub step. The first sub step can comprise providing an alcohol, for example an alkyl alcohol such as ethanol to the reaction chamber. Alternatively, the first sub step can comprise providing a carboxylic acid such as formic acid or ethanoic acid to the reaction chamber. The second sub step comprises providing an oxidizing agent, for example an oxygen-containing gas or gas mixture, to the reaction chamber. A suitable oxidizing agent is O₂. Optionally, the first and second sub step are separated by a purge. Then, the method ends (460).

In an exemplary embodiment, an embodiment of a process according to FIG. 4 is described. In this embodiment, the reducing agent is ethanol, the oxidizing agent is O₂, the cleaning agent is hexafluoroacetylacetone, and the cleaning residue removal agent comprises a first sub step and a second sub step. The first sub step comprises providing ethanol to the reaction chamber. The second sub step comprises providing O₂ to the reaction chamber. Using such a process, excellent process uniformity can be obtained.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

1. A method for cleaning a substrate, the method comprising:
providing a substrate comprising a dielectric and an oxidized metal surface, to a reaction chamber;
providing a reducing agent to the reaction chamber, thereby contacting the substrate with the reducing agent and converting the oxidized metal surface to a metal surface;
providing an oxidizing agent to the reaction chamber, thereby contacting the substrate with the oxidizing agent and oxidizing metal contaminants on the dielectric surface, thus forming oxidized metal contaminants; and,
providing a cleaning agent to the reaction chamber, thereby contacting the substrate with the cleaning agent and removing the oxidized metal contaminants from the substrate,
wherein the oxidized metal contaminants comprise one or more of cobalt and copper.

2. The method according to claim 1 wherein the oxidizing agent is an oxygen-comprising gas or gas mixture.

3. The method according to claim 1 wherein the oxidizing agent is a gas selected from O₂, O₃, H₂O, H₂O₂, and mixtures thereof.

4. The method according to claim 1 wherein the reducing agent comprises an alcohol.

5. The method according to claim 1 wherein the cleaning agent comprises a beta diketonate.

6. The method according to claim 1 wherein the cleaning agent comprises a compound that comprises a cyclopentadienyl group.

7. The method according to claim 1 wherein the cleaning agent comprises one or more carbonyl-containing compounds.

8. The method according to claim 1 wherein the cleaning agent comprises a carboxylic acid.

9. The method according to claim 1 wherein the step of providing a cleaning agent to the reaction chamber is followed by a step of providing a further oxidizing agent to the reaction chamber.

10. The method according to claim 9 wherein the step of providing a further oxidizing agent to the reaction chamber comprises, in the following order, providing O₂ to the reaction chamber in an O₂ pulse and providing H₂O to the reaction chamber in a H₂O pulse.

11. The method according to claim 1 wherein the step of providing a cleaning agent to the reaction chamber is followed by a step of providing a cleaning residue removal agent to the reaction chamber.

12. The method according to claim 11 wherein the cleaning residue removal agent comprises an alcohol.

13. The method according to claim 12 wherein the alcohol comprises an alkyl alcohol.

14. The method according to claim 13 wherein the alkyl alcohol is selected from methanol, ethanol, isopropanol, and isobutanol.

15. The method according to claim 11 wherein the cleaning residue removal agent comprises a further oxidizing agent.

16. The method according to claim 15 wherein the step of providing a cleaning residue removal agent to the reaction chamber comprises, in the following order, providing O₂ to the reaction chamber in an O₂ pulse and providing H₂O to the reaction chamber in a H₂O pulse.

17. The method according to claim 11 wherein the step of providing a cleaning residue removal agent to the reaction chamber comprises a first sub step and a second sub step, the first sub step comprising providing an alcohol to the reaction chamber, and the second sub step comprising providing an oxidizing agent to the reaction chamber.

18. A method for selectively depositing a material on a substrate comprising a metal surface and a dielectric surface, comprising the steps:
cleaning the substrate by means of a method according to claim 1;
selectively depositing the material on one of the metal surface or the dielectric surface.

19. The method according to claim 18 wherein the material comprises a metal, and wherein the metal is deposited on the metal surface.

20. A system comprising one or more reaction chambers, a cleaning gas source, and a controller, the controller being configured for causing the system to carry out a method according to claim 1.
